(19) United States
(12) Patent Application Publication
(10) Pub. No.: US 2026/0023901 A1
(43) Pub. Date: Jan. 22, 2026

(54) COMPUTATIONAL FLUID DYNAMICS SYSTEM AND RELATED METHODS

(71) Applicant: EAGLE TECHNOLOGY, LLC, MELBOURNE, FL (US)

(72) Inventors: JOHN PENUEL, INDIAN HARBOUR BEACH, FL (US); MICHAEL C. GARRETT, MELBOURNE, FL (US); MARK D. RAHMES, MELBOURNE, FL (US)

(21) Appl. No.: 18/773,706

(22) Filed: Jul. 16, 2024

(51) Int. Cl. G06F 30/28

(52) U.S. Cl. CPC G06F 30/28

(57) ABSTRACT

A computational fluid dynamics system may include a quantum computing circuit and a processor. The processor may be configured to generate and store a union mesh table representing a plurality of point groups, with at least some points being shared among different groups, and each point having a same property. The processor may be further configured to cooperate with the quantum computing circuit to perform a fluid dynamic computation based on a streaming fluid velocity vector and the union mesh table.

### TECHNICAL FIELD

The present disclosure relates generally to quantum computing systems and associated algorithms. More particularly, the present disclosure relates to quantum computing for computational fluid dynamics modeling and related methods.

### BACKGROUND

Quantum computers use the properties of quantum physics to store data and perform computations. Quantum computers include specialized hardware on which qubits are stored, controlled and/or manipulated in accordance with a given application. The term “qubit” is used in the field to refer to a unit of quantum information. The unit of information can also be called a quantum state. A single qubit is generally represented by a vector a|0>+b|1>, where a and b are complex coefficients and |0> and |1> are the basis vectors for the two-dimensional complex vector space of single qubits. At least partially due to the qubit structure, quantum computers use the properties of quantum physics to perform computation, enabling advantages that can be applied to certain problems that are impractical for conventional computing devices.

Despite the advantages of such systems, further developments in the utilization of quantum computing techniques may be desirable in certain applications, such as for computational fluid dynamics, for example.

### SUMMARY

A computational fluid dynamics system may include a quantum computing circuit and a processor. The processor may be configured to generate and store a union mesh table representing a plurality of point groups, with at least some points being shared among different groups, and each point having a same property. The processor may be further configured to cooperate with the quantum computing circuit to perform a fluid dynamics computation based on a streaming fluid velocity vector and the union mesh table.

By way of example, the points may comprise pixels (in the case of a 2D implementation), or voxels (in the case of a 3D implementation). Also by way of example, the point groups may have boundaries defined by rectangles (in the case of a 2D implementation), or rectangular prisms (in the case of a 3D implementation). In an example implementation, the property of a given point may be that the point is solid or fluid.

In some embodiments, the processor may be further configured to generate and store a hash table representation of the plurality of point groups, and cooperate with the quantum computing circuit to separately perform the fluid dynamic computation based on the hash table. The processor may instead or additionally be configured to generate and store a quad tree or octree representation of the plurality of point groups, and cooperate with the quantum computing circuit to separately perform the fluid dynamic computation based on the quad tree or octree representation. In an example implementation, the processor may be configured to cooperate with the quantum computing circuit to perform the fluid dynamics computation based on a Carleman Linearized Lattice Boltzmann algorithm.

A related computational fluid dynamics method may include generating and storing at a processor a union mesh table representing a plurality of point groups, with at least some points being shared among different groups, and each point having a same property. The method may also include, at the processor, cooperating with a quantum computing circuit to perform a fluid dynamics computation based on a streaming fluid velocity vector and the union mesh table.

A related non-transitory computer-readable medium may have computer-executable instructions for causing a processor to perform steps including generating and storing a union mesh table representing a plurality of point groups, with at least some points being shared among different groups, and each point having the same property. A further step may include cooperating with a quantum computing circuit to perform a fluid dynamic computation based on a streaming fluid velocity vector and the union mesh table.

### BRIEF DESCRIPTION OF THE DRAWINGS

FIG. 1 is a schematic block diagram of a computational fluid dynamics system in accordance with an example embodiment.

FIG. 2 is a schematic diagram illustrating a computational fluid dynamics problem to be solved by the system of FIG. 1 of a fluid velocity vector streaming toward and bouncing back from a solid node.

FIG. 3 is a graph illustrating a pixel union mesh representation of point groups which may be used by the system of FIG. 1 in an example embodiment.

FIG. 4 is a point grid for a quadtree representation of the points shown in FIG. 3.

FIG. 5 is a quadtree diagram of the point grid of FIG. 4.

FIG. 6 is a 2D image diagram including solid and fluid points for which computational fluid dynamics calculations are performed by the system of FIG. 1 in an example embodiment.

FIG. 7 is a 2D image diagram illustrating the inverse case of FIG. 6 in which the solid and fluid points are reversed.

FIG. 8 is another 2D image diagram including solid and fluid points for which computational fluid dynamics calculations are performed by the system of FIG. 1 in an example embodiment.

FIG. 9 is a flow diagram illustrating method aspects associated with the system of FIG. 1.

FIGS. 10 and 11 are schematic diagrams illustrating example quantum circuit implementations for the system of FIG. 1.

FIG. 12 is a 2D image diagram including solid and fluid points for which computational fluid dynamics calculations are performed by the system of FIG. 1 in another example embodiment.

### DETAILED DESCRIPTION

The present description is made with reference to the accompanying drawings, in which exemplary embodiments are shown. However, many different embodiments may be used, and thus the description should not be construed as limited to the particular embodiments set forth herein. Rather, these embodiments are provided so that this disclosure will be thorough and complete. Like numbers refer to like elements throughout.

By way of background, classical computational fluid dynamics (CFD) approaches often involve computing a set of geometric (e.g., rectangular) prisms for a set of solid/fluid data points. From the mesh of prisms, a variety of CFD solver software approaches may be used in classical computing to perform CFD calculations. Generally speaking, meshing seeks to define volumes that do not overlap.

Another classical approach is octree/quadtree representation of pixel/voxel data. In this approach, a domain is subdivided into 2/4/8 (for 1D, 2D, 3D) equal sections until the structure inside the subdivided area is uniform. In this approach, to determine if a point a solid of fluid, the tree is traversed from the root node to the leaf node. However, in some circumstances this may require multiple steps to traverse the tree all of the way to the leaf node, which may be multiple layers down and on separate branches, for example.

A typical fluid dynamics scenario involves determining when a fluid velocity vector is “streaming” into a solid node (e.g., a wall or object), and how it will react. This scenario is represented in the diagram 35 of FIG. 2. The Lattice Boltzmann Method (LBM) is one CFD approach which may be used to model this scenario. The LBM discretizes space into a grid of points and discretizes velocity vectors into a fixed set. When a fluid velocity vector is “streaming” into a solid node (wall/object), the velocity vector is “bounced back”. To do so, a list needs to be stored to test whether a point is a fluid or solid.

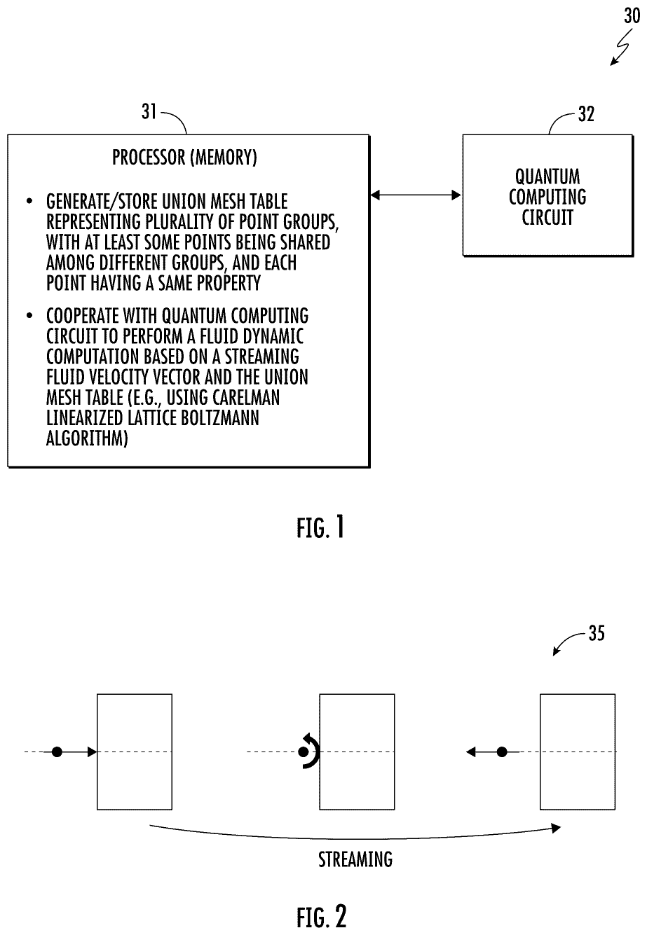

Referring additionally to FIG. 1, a computational fluid dynamics system 30 in accordance with an example embodiment which utilizes quantum computing to solve such fluid dynamics models is now described. The system 30 illustratively includes a processor 31 and a quantum computing circuit 32 coupled to the processor. The processor 31 and associated memory may be implemented using classical computing components (e.g., a microprocessor and non-transitory computer-readable medium having computer-executable instructions for performing the operations described herein), and example configurations of the quantum computing circuit 32 will be discussed further below. The foregoing problem is one which may advantageously be solved much faster than with a classical computer. However, the drawback of doing so on a quantum computer is that loading large lists to a quantum computer/circuit, such as the fluid/solid list noted above, may cause a significant bottleneck and can actually negate the gains otherwise achieved.

The system 30 uses a more compact representation of fluid/solid points to advantageously reduce the number of lookup operations the quantum computing circuit 32 is required to perform. This technique is described herein as Voxel Union Meshing (VUM), which provides a relatively compact representation of the fluid/solid points. This approach derives from the answer to the question: “is the node (x, y, z) a solid or a fluid node?”

More particularly, in an example VUM approach the minimum set of rectangular prisms that completely cover a given set of pixels (2D) or voxels (3D) with a specific property is generated. Any pixel/voxel with a specific property may be covered by one or more rectangles/rectangular prisms. The union of all rectangles/rectangular prisms is the equivalent set of pixels/voxels with the specific property. As such, this approach maximizes the number of rectangles/rectangular prisms that any specific pixel/voxel appears in. This leads to faster determination in answering the above-noted question, i.e., does the pixel/voxel have the specific property (or not)?

This may be done relatively fast through simplified inequalities. For example, prism_lower_x<=x<=prism_upper_x, and similar for y, z points. This advantageously provides for probabilistically answering the question sooner, so that further evaluation may be skipped to save processing resources and time. By way of example, the quantum computing circuit 32 may implement a Carleman Linearized version of the LBM to perform these operations.

More particularly, in an example VUM approach volumes of points are overlapped to speed up lookup operations, as opposed to typical meshing approaches which seek to define volumes that do not overlap. Referring to the graph 37 of FIG. 3, an example representation of a VUM for a plurality of solid points 38 is shown. The union of rectangles or rectangular prisms 39 can form a 1D, 2D, 3D, etc., mesh structure (2D in the present example). The union of all points/voxels is covered by the set of rectangular prisms. In this example, num_points=13 and num prisms=6. Rather than using a hash table or list of points, as in typical meshing approaches, the VUM approach utilizes a list of prisms.

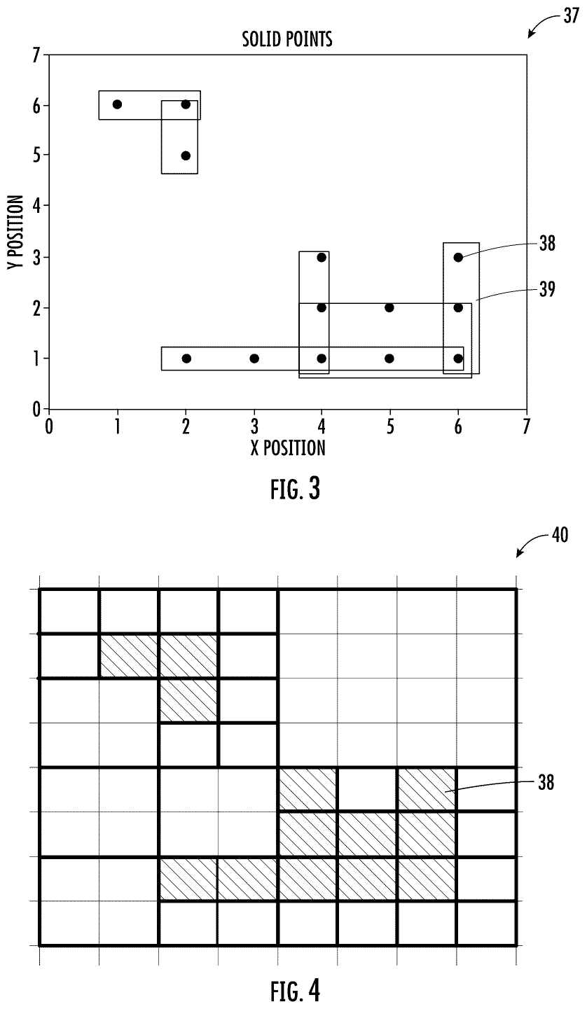

By way of comparison, the graph 40 of FIG. 4 provides a grid, and the diagram 50 of FIG. 5 provides a tree diagram, of the same thirteen solid points of the graph 37 in accordance with a quadtree representation, in which:

$$num\_quadtree \_nodes = 1 + 4 + 12 + 32 = 49$$

$$quadtree\_depth = 3.$$

While the quadtree depth might otherwise provide for faster lookups, the tradeoff is that it may involve more data loading, which may increase the overall processing time. In particular, in many if not most cases the number of prisms will be less than or equal to the number of points, and only in extreme cases will the number of prisms approach the number of points. As such, the VUM approach takes advantage of this by allowing for a much more compact list of prisms, as opposed to a list or hash table of points, which in many cases will yield the least data loading to advantageously reduce bottlenecking at the quantum computing circuit 32, as may occur with more traditional (data loading intensive) approaches.

The processor 31 is configured to generate and store a voxel union mesh table representing a plurality of point 38 groups (here rectangular prisms 39), with at least some points being shared among different groups, and each point having a same property, which in the present example is solid. The processor 31 is further configured to cooperate with the quantum computing circuit 32 to perform a fluid dynamic computation based on a streaming fluid velocity vector and the union mesh table. That is, the processor 31 provides the optimized set of rectangular prisms 39 to the quantum computing circuit 32, which in the present example is configured to solve Computational Fluid Dynamics problems using the Carleman Linearized Lattice Boltzmann Method (although other suitable quantum computing approaches may be used in different embodiments).

In one example implementation of this approach, the quantum computing circuit 32 may be configured with logic to implement lookups for a streaming term as follows:

$$\tilde{S} ( {f}_{i} ( {x}_{a} ) , {f}_{j} ( {x}_{β} ) ) = \{ \begin{matrix}- 1 & if {x}_{β} = {x}_{α} ( local to node {x}_{α} ) \\ & and {x}_{α} is a fluid node \\ & and {c}_{j} = {c}_{i} \neq \vec{0} ( same velocity vector ) \\ 1 & if {x}_{β} = {x}_{α} - {c}_{i} ( not local to node {x}_{α} ) \\ & and {x}_{α} is a fluid node \\ & and {x}_{β} is a fluid node \\ & and {c}_{j} = {c}_{i} \neq \vec{0} ( same velocity vector ) \\ 1 & if {x}_{β} = {x}_{α} ( local to node {x}_{α} ) \\ & and {x}_{α} is a fluid node \\ & and {x}_{α} - {c}_{i} is a solid node \\ & and {c}_{j} = {c}_{i} \neq \vec{0} ( reverse velocity vector ) \\ 0 & else\end{matrix} .$$

Continuing with the examples of FIGS. 3-5, for the VUM there will be six prisms (and therefore six items for which lookups have to be performed by the quantum computing circuit 32) as follows:

| | |
|---|---|
| prisms = | [ |
| | [[6, 6], [1, 3]] |
| | [[1, 2], [6, 6]] |
| | [[2, 6], [1, 1]] |
| | [[2, 2], [5, 6]] |
| | [[4, 6], [1, 2]] |
| | [[4, 4], [1, 3]] |
| | ] |

On the other hand, a conventional hash table of the thirteen solid points 38 would be as follows:

```
solid_points_list = [
  (4, 1),
  (4, 2),
  (4, 3),
  (5, 1),
  (5, 2),
  (6, 1),
  (6, 2),
  (2, 5),
  (2, 6),
  (2, 1),
  (3, 1),
  (1,6),
  (6,3)
]
```

These thirteen items would require thirteen lookup operations to be performed by the quantum computing circuit 32. Moreover, a quadtree representation would require forty-nine items, and therefore forty-nine lookups to be performed by the quantum computing circuit 32. As such, in many instances the VUM representation will accordingly provide more efficient storage and/or probabilistically more efficient lookups. Other enhancements, such as sorting or placing vertices into a tree structure, may also be incorporated. In addition, overlap between VUM prisms implies that an answer to the above-noted question may be found faster than the other approaches because evaluation may stop as soon as the first inclusion is identified.

In some embodiments, a hybrid approach may be used in which the processor 31 utilizes the smallest of the above described approaches. In accordance with one example implementation, the processor may pass along to the quantum computing circuit 32 the output from one of the following which has the least number of items:
1. Original Hash Table/List of Solid Nodes;
2. Original Hash Table/List of Fluid Nodes;
3. Octree/Quadtree representation;
4. Voxel Union Mesh (VUM) (of solid nodes); or
5. Voxel Union Mesh (VUM) (of fluid nodes).

In accordance with another example implementation, multiple representations may be used with parallel lookup operations, and the approach selected is whichever one returns the fastest result.

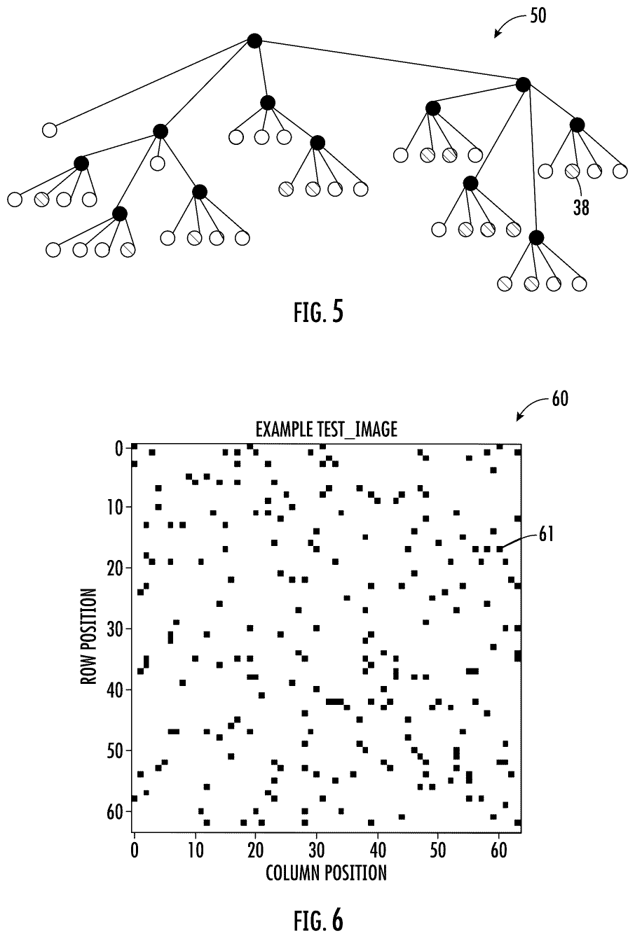

The foregoing will be further understood with reference to several example use cases now described with reference to FIGS. 6-8. In the plot 60 of FIG. 6, an example test 64Δ64 2D image representation is shown in which the points 61 (pixels/voxels) are solid points, and the remaining points (white space) are fluid points. This image is relatively noisy, plus the pixels 61 occupy only about 5% of the total image and are spaced apart in relatively discontinuous regions with little structure. A numerical study was performed by generating 500 randomized images with the same properties as FIG. 6. From the study, the resulting hash table, quad tree, and VUM would have the following sizes:

| | Min | Median | Max |
|---|---|---|---|
| Hash table size: | 159 | 204.0 | 241 |
| Quad tree size: | 505 | 619.0 | 712 |
| Voxel union mesh size: | 148 | 186.0 | 221 |

The approximate VUM reduction in median size from the hash table is 9%, and from the quad tree the VUM reduction is approximately 70%. Thus, in this particular study, there is not a significant reduction as between the VUM and the hash table, and in this case the hash table approach may be the first one to finish if processed in parallel, for example.

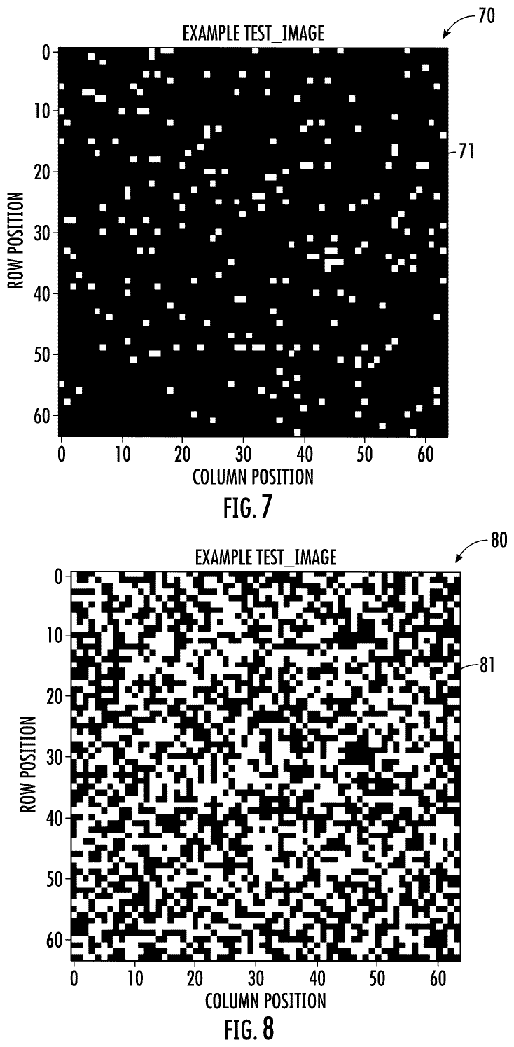

Nonetheless, an inverted version of the plot 60 is provided in the plot 70 of FIG. 7. Here, the solid and fluid points are inverted, such that solid points 71 are now the vast majority. While this image is still noisy with little structure, the solid points now fill ˜95% of the total image pixels, and there are also many continuous regions. Similarly, a numerical study with 500 randomized images similar to FIG. 7. The resulting sizes were:

| | Min | Median | Max |
|---|---|---|---|
| Hash table size: | 3845 | 3890 | 3937 |
| Quad tree size: | 1214 | 1461.0 | 1674 |
| Voxel union mesh size: | 194 | 238.0 | 279 |

The approximate VUM reduction in median size from the hash table is now approximately 94%, and from the quad tree is approximately 84%. Thus, in this case the VUM approach provides for significantly improved storage and lookup capabilities, greatly reducing the bottleneck for quantum computing.

In the plot 80 of FIG. 8, still another example test 64×64 2D image representation is shown in which the points 81 (pixels/voxels) are solid points, and the remaining points (white space) are fluid points. This image is relatively noisy, and the pixels 81 occupy about 50% of the total image and have a dense content, although the pixels are spaced apart in relatively discontinuous regions with little structure. A study of 500 randomized images similar to FIG. 8 was performed and the resulting statistics were:

| | Min | Median | Max |
|---|---|---|---|
| Hash table size: | 1961 | 2047.0 | 2152 |
| Quad tree size: | 3012 | 3094.0 | 3187 |
| Voxel union mesh size: | 855 | 904 | 945 |

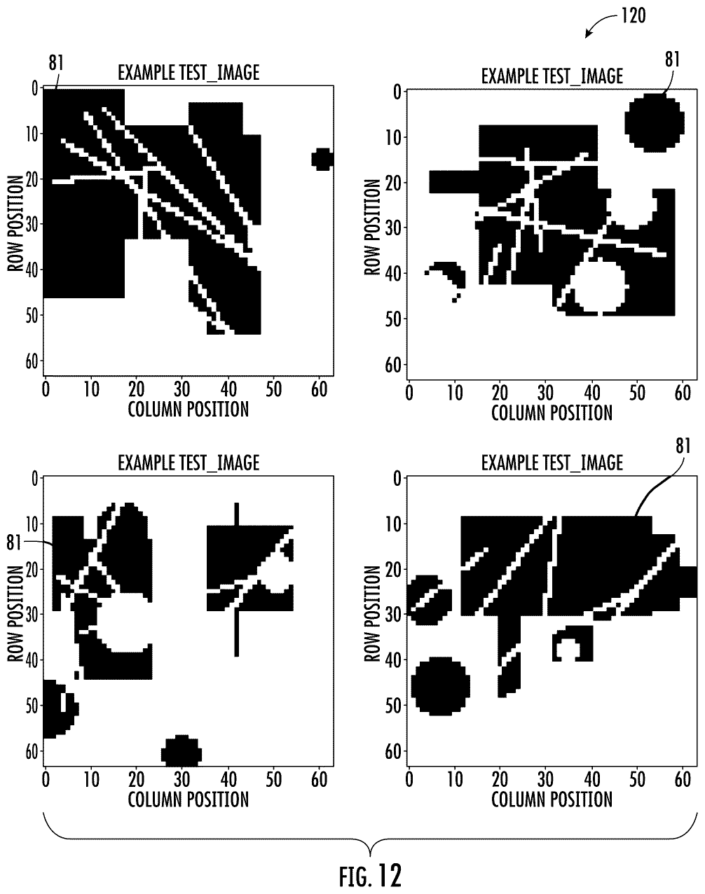

Here again, this example demonstrates a notable improvement using the VUM approach in terms of storage and/or lookup operations required. In the plot 120 of FIG. 12, still other example test 64×64 2D image representations are shown in which the points 81 (pixels/voxels) are solid points, and the remaining points (white space) are fluid points. This imagery includes a mixture of rectangles, circles, and lines which are structurally correlated but irregular. A study of 500 randomized images similar to FIG. 12 was performed and the resulting statistics were:

| | Min | Median | Max |
|---|---|---|---|
| Hash table size: | 475 | 1446.0 | 2925 |
| Quad tree size: | 324 | 724.0 | 1416 |
| Voxel union mesh size: | 21 | 97.0 | 191 |

Once again, this example demonstrates a significant improvement using the VUM approach in terms of storage and/or lookup operations required.

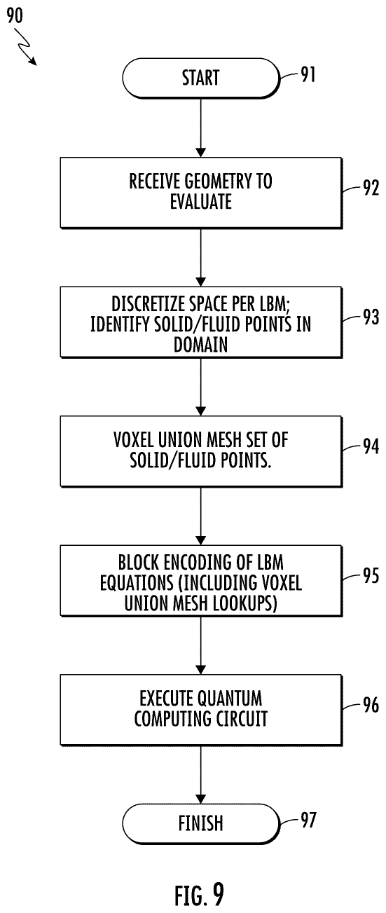

Turning to the flow diagram 90 of FIG. 9, example method aspects which may be performed by the system 30 are now described. Beginning at Block 91, the geometry to be evaluated may be received by the processor 31, at Block 92. From this volume, the processor 31 may discretize the image space for compatibility with the LBM approach, and identify solid/fluid points within the domain, at Block 93, as will be appreciated by those skilled in the art. The processor 31 may then determine the VUM of solid and/or fluid points in the image, at Block 94. It should be noted that the processor 31 at this point may also determine hash table and/or quad tree representations as well, if multiple/parallel approaches are to be used, as discussed further above. The processor 31 may then perform block encoding of LBM equations (including VUM lookups), at Block 95, for utilization by the quantum computing circuit 32. At this point, the quantum computing processing may be performed by the quantum computing circuit 32 (Block 96), e.g., using the Carleman Linearized version of the LBM, as noted above. The method of FIG. 9 illustratively concludes at Block 97.

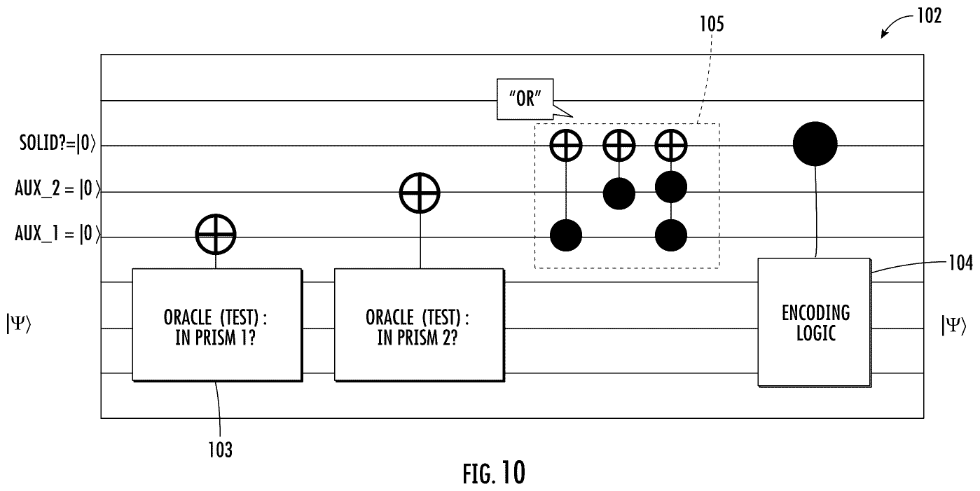

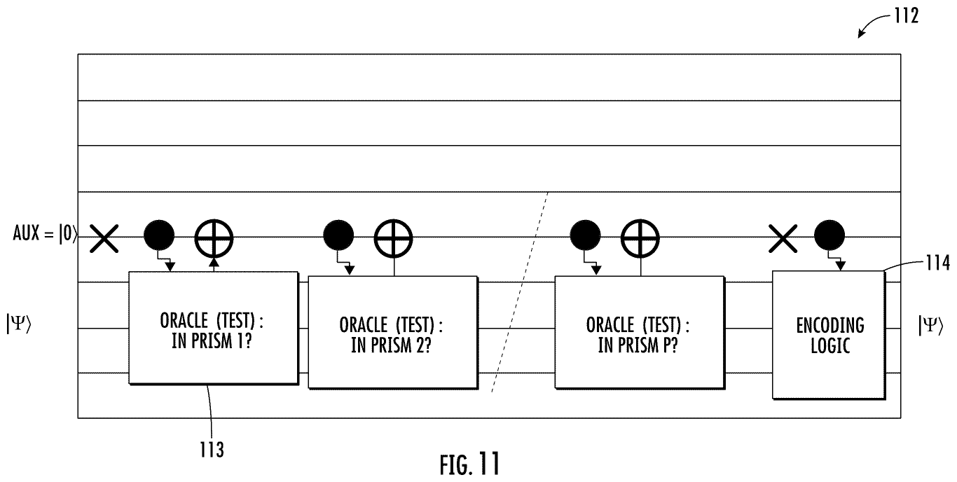

Example quantum computing circuitry implementations 102 and 112 are shown in FIGS. 10 and 11, respectively, which may be utilized for the quantum computing circuit 32. As discussed above, for the present fluid dynamics application, the quantum computing circuit 32 is configured to solve the problem “is the node solid or fluid?”. The quantum logic circuits 102 and 112 are two example approaches to translate this question into an equivalent one for quantum computing, namely “is the node in any prism?”, for which Oracle test logic 103/113 are utilized as shown. The quantum logic circuits 102 and 112 further include respective encoding logic circuitry 104/114, and the circuitry 102 further includes OR logic circuitry 105.

In the example configurations, VUM may advantageously provide a reduction in the number of tests required, i.e., by reducing circuit depth. Once a test is positive, the remaining tests may be executed as identity operations to save quantum processing resources. Furthermore, the prisms may be ordered to probabilistically find the answer sooner, e.g., from largest to smallest. As discussed above with reference to FIG. 7, “inverse” VUM operations may also be implemented in the circuitry 102, 112 in some embodiments.

In other applications, the above-noted approach may be extended to other lattice structures, e.g., a 2D equilateral triangle lattice, 3D equilateral tetrahedron lattice. Other lattices with translational symmetry are also possible, as will be appreciated by those skilled in the art. Here again, a first step may be to consider binary properties, such as whether the node is a “solid” or “not solid”, for example. However, the above-described approach may also be extended to other properties as well, with one VUM structure being used for each property. One example use case is to create respective VUMs for different types of land use features, such as forest, road, farm, water body, etc. As noted above, the VUMs may overlap, and the VUM approach is intended to answer the question of whether a given pixel is a “forest” pixel or not, for example. Again, the same VUM data may also be represented with a hash table lookup or tree structure in some embodiments, if alternate or parallel processing are desired. Further details regarding land use feature determination are provided in co-pending application Ser. No. 18/616, 332 filed Mar. 26, 2024, which is hereby incorporated herein in its entirety by reference.

The foregoing approach advantageously provides a novel data structure (i.e., Voxel Union Mesh) for storing and performing lookup operations on grid point (i.e., voxel) data. In the example approach, the minimal VUM is calculated that ensures the maximum overlap of rectangular prisms covering individual voxels/points, and the method may run in polynomial time. Other technical advantages of the VUM approach are that the VUM representation is lossless, and that the VUM representation may accommodate non-convex geometry. In some cases, the VUM data structure provides a smaller storage footprint than other approaches to thereby provide faithful/lossless compression of voxel data, smaller data files for transfer, and/or smaller data files for database/archival storage. As discussed above, in many instances the VUM data structure may provide faster lookup operations, and may advantageously utilize the Lattice Boltzmann Method for Computational Fluid Dynamics for the quantum computing circuit 32.

A related non-transitory computer-readable medium may have computer-executable instructions for causing the processor 31 to perform steps including generating and storing a union mesh table representing a plurality of point groups, with at least some points being shared among different groups, and each point having a same property. A further step may include cooperating with the quantum computing circuit 32 to perform a fluid dynamic computation based on a streaming fluid velocity vector and the union mesh table, as discussed further above.
1. Many modifications and other embodiments will come to the mind of one skilled in the art having the benefit of the teachings presented in the foregoing descriptions and the associated drawings. Therefore, it is understood that the disclosure is not to be limited to the specific embodiments disclosed, and that modifications and embodiments are intended to be included within the scope of the appended claims.

1. A computational fluid dynamics system comprising:
a quantum computing circuit; and
a processor configured to
generate and store a union mesh table representing a plurality of point groups, with at least some points being shared among different groups, and each point having a same property, and
cooperate with the quantum computing circuit to perform a fluid dynamic computation based on a streaming fluid velocity vector and the union mesh table.

2. The computational fluid dynamics system of claim 1 wherein the points comprise pixels.

3. The computational fluid dynamics system of claim 1 wherein the points comprise voxels.

4. The computational fluid dynamics system of claim 1 wherein the point groups have boundaries defined by rectangles.

5. The computational fluid dynamics system of claim 1 wherein the point groups have boundaries defined by rectangular prisms.

6. The computational fluid dynamics system of claim 1 wherein the property of the points comprises that the point is solid.

7. The computational fluid dynamics system of claim 1 wherein the property of the points comprises that the point is fluid.

8. The computational fluid dynamics system of claim 1 wherein the processor is further configured to generate and store a hash table representation of the plurality of point groups, and cooperate with the quantum computing circuit to separately perform the fluid dynamic computation based on the hash table.

9. The computational fluid dynamics system of claim 1 wherein the processor is further configured to generate and store a quad tree or octree representation of the plurality of point groups, and cooperate with the quantum computing circuit to separately perform the fluid dynamic computation based on the quad tree or octree representation.

10. The computational fluid dynamics system of claim 1 wherein the processor is configured to cooperate with the quantum computing circuit to perform the fluid dynamic computation based on a Carleman Linearized Lattice Boltzmann algorithm.

11. A computational fluid dynamics method comprising:
generating and storing at a processor a union mesh table representing a plurality of point groups, with at least some points being shared among different groups, and each point having a same property; and
at the processor, cooperating with a quantum computing circuit to perform a fluid dynamic computation based on a streaming fluid velocity vector and the union mesh table.

12. The method of claim 11 wherein the points comprise pixels, and the point groups have boundaries defined by rectangles.

13. The method of claim 11 wherein the points comprise voxels, and the point groups have boundaries defined by rectangular prisms.

14. The method of claim 11 wherein the property of the points comprises that the point is solid.

15. The method of claim 11 wherein the property of the points comprises that the point is fluid.

16. A non-transitory computer-readable medium having computer-executable instructions for causing a processor to perform steps comprising:
generating and storing a union mesh table representing a plurality of point groups, with at least some points being shared among different groups, and each point having a same property; and
cooperating with a quantum computing circuit to perform a fluid dynamic computation based on a streaming fluid velocity vector and the union mesh table.

17. The non-transitory computer-readable medium of claim 16 wherein the points comprise pixels, and the point groups have boundaries defined by rectangles.

18. The non-transitory computer-readable medium of claim 16 wherein the points comprise voxels, and the point groups have boundaries defined by rectangular prisms.

19. The non-transitory computer-readable medium of claim 16 wherein the property of the points comprises that the point is solid.

20. The non-transitory computer-readable medium of claim 16 wherein the property of the points comprises that the point is fluid.
